(19) United States
(12) Patent Application Publication
(10) Pub. No.: US 2002/0096744 A1
(43) Pub. Date: Jul. 25, 2002

(54) Integrated circuits protected against reverse engineering and method for fabricating the same using etched passivation openings in integrated circuits

(75) Inventors: Lap-Wai Chow, South Pasadena, CA (US); James P. Baukus, Westlake Village, CA (US); William M. Clark JR., Camarillo, CA (US)

Correspondence Address: Victor Repkin, Esq., c/o LADAS & PARRY, Suite 2100, 5670 Wilshire Boulevard, Los Angeles, CA, 90036-5679, US

(73) Assignee: HRL Laboratories, LLC

(21) Appl. No.: 09/768,905

(22) Filed: Jan. 24, 2001

(51) Int. Cl. H01L 23/58

(52) U.S. Cl. 257/629

(57) ABSTRACT

Semiconducting devices, including integrated circuits, protected from reverse engineering comprising passivation openings made in a passivation layer. When a reverse engineer etches away the passivation layer, underlying metal layers and/or other elements of the device are destroyed making the reverse engineering impossible. Top metal layer may remain intact. A method for fabricating such devices.

### I. BACKGROUND OF THE INVENTION

1. Field of the Invention

This invention relates to the field of the prevention of reverse engineering of integrated circuits and/or making such reverse engineering so difficult and time-consuming as to make reverse engineering of integrated circuits non-feasible.

More particularly, this invention relates to using, in order to prevent and/or discourage such reverse engineering, openings etched in the passivation layer, typically, the uppermost insulating layer disposed atop an integrated circuit.

2. Description of the Related Art

The design and development of semiconductor integrated circuits require a thorough understanding of the complex structures and processes and involve many man-hours of work requiring high skill, costing considerable sums of money.

In order to avoid these expenses, some developers stoop to the contentious practice of reverse engineering, disassembling existing devices manufactured by somebody else, and closely examining them to determine the physical structure of the integrated circuit, followed by copying the device. Thus, by obtaining a planar optical image of the circuits and by studying and copying them, typically required, product development efforts are circumvented.

Such practices harm the true developer of the product and impairs its competitiveness in the market-place, because the developer had to expend significant amounts of resources for the development, while the reverse engineer did not have to.

A number of approaches have been used in order to frustrate such reverse engineering attempts, particularly in the field of semiconductor integrated circuits.

For instance, U.S. Pat. No. 5,866,933 to Baukus, et. al. teaches how transistors in complementary metal oxide-semiconductor (CMOS) circuit can be connected by implanted, hidden and buried lines between the transistors. This hiding is achieved by modifying the p+ and n+ source/drain masks. The implanted interconnections are further used to make a 3-input AND-circuit look substantially the same as a 3-input OR-circuit.

Furthermore, U.S. Pat. No. 5,783,846 to Baukus, et. al. and U.S. Pat. No. 5,930,663 to Baukus et. al. teach a further modification in the source/drain implant masks, so that the implanted connecting lines between transistors have a gap inserted, the length of which is approximately the length of the feature size of the CMOS technology being used. These gaps are called “channel blocks.”

If the gap is “filled” with one kind of implant (depending on whether the implanted connecting line is p or n), the line conducts; if another kind of implant is used for the gap-filling, the line does not conduct. The reverse engineer must determine connectivity on the basis of resolving the “n” or “p” implant at the minimum feature size of the channel block. In addition, transistor sizes and metal connection routings are modified, in order to deprive the reverse engineer of using clues which he can utilize to find inputs, outputs, gate lines and so on as keys to the circuit functionality.

Practicing the inventions taught in the above-mentioned patents to secure an integrated circuit causes the reverse engineer to perform steps that are not always needed. These steps include: decomposing the circuit layer by layer, careful processing of each layer (which usually must include an etching step) followed by imaging of the layer with exact registration to other layers.

Once a particular standard circuit functionality has been determined, the reverse engineer will attempt to find some signature in the metal layers of that standard circuit which can exactly indicate the presence of that particular standard circuit in other places in the integrated circuit. If this can be done, that information can be entered into the reverse engineer's data base and automatic pattern recognition of the metal pattern is used to determine the circuit, without need for the extensive delayering. This would save considerable time and effort.

Therefore, there still exists a need for an inexpensive, easy-to-implement defensive method which can help to provide the enhanced protection against the reverse engineering of semiconductor integrated circuits, in particular to make such a signature impossible to determine. The present invention provides such a method.

### II. SUMMARY OF THE INVENTION

Modern integrated circuits comprise a plurality of layers, such as metal layers and insulating layers, deposited and patterned to effect the circuit design. On top of such layers a layer of passivating material, such as an oxide or nitride, is typically deposited in order to protect the integrated circuit from environmental hazards.

When a reverse engineer begins the process of reverse engineering, he typically etches away the passivation layer in order to be able to see the highest (from the top) level of metal. Then, he observes and records that metal layer data, followed by further etching in order to remove the oxide between metal layers.

The gist of this invention is to provide an extra opening in the passivation layer, for example, an opening that is not required for a contact metal. In this case, normal, careful deprocessing by the reverse engineer will lead to the destruction of important elements and data because of the deeper etching that will occur in the region of the passivation opening. In other words, in order to learn the design of the integrated circuit, the reverse engineer cannot help destroying important portions of the circuit. This kind of protection will substantially assist in protecting the integrated circuit against reverse engineering.

A first aspect of the invention provides a semiconducting device adapted to prevent and/or to thwart reverse engineering, comprising an insulating layer disposed on a semiconductor substrate, a plurality of metal layers, said metal layers of said plurality being separated by said insulating layer, said plurality of said metal layers comprising a top metal layer and a number of lower metal layers disposed below said top metal layer, a passivation layer, said passivation layer being disposed on top metal layer of said plurality of said metal layers, and a passivation opening defined within said passivation layer, wherein said passivation opening has a location above one or more said lower metal layers, said location lying in a first vertical plane, and said top metal layer lying in a second vertical plane, said first vertical plane being spatially separated from said second vertical plane.

A second aspect of the invention provides a method for preventing and/or thwarting reverse engineering, comprising steps of providing an insulating layer disposed on a semiconductor substrate, providing a plurality of metal layers whereby said metal layers of said plurality are separated by said insulating layer, said plurality of said metal layers comprising a top metal layer and a number of lower metal layers disposed below said top metal layer, providing a passivation layer whereby said passivation layer is disposed on top metal layer of said plurality of said metal layers, and forming a passivation opening defined by said passivation layer, said passivation opening being provided at a location above one or more said lower metal layers, said location being spatially separated from said top metal layer.

### III. BRIEF DESCRIPTION OF THE DRAWINGS

The features and advantages of the present invention will become better understood with regard to the following description, appended claims, and accompanying drawings where

FIG. 1 is schematic partial cross-section view of two top metal layers of the integrated circuit separated by an oxide layer.

FIG. 2 is an exploded view of a typical structure of FIG. 1, showing top view after the passivation layer has been removed.

FIG. 3 is a schematic cross-section view showing the passivation opening and the effect of using an etchant to remove the passivation layer in the region of the opening.

FIG. 4 is a schematic diagram illustrating an embodiment of this invention wherein the protection against reverse engineering is accomplished by disabling the reading of memory function.

### IV. DETAILED DESCRIPTION OF THE INVENTION

This invention can be used on any semiconducting device, including CMOS, bipolar silicon or group III-group V integrated circuits.

FIG. 1 shows a typical cross-section view of a part of a device comprising a plurality of metal layers. Top metal layer 1 and a next metal layer 2 are separated by an insulating layer 3, preferably, a silicon oxide layer. Each metal layer 1 and 2 has a preferable thickness of about 200 Angstroms, and the insulating layer 3 has a thickness preferably within a range of between 3,000 Angstroms and 5,000 Angstroms. The insulating layer 3 is disposed on a semiconducting substrate, such as that used in integrated circuits (not shown). Only two metal layers 1 and 2 are shown on FIGS. 1-3 for the purposes of illustration of the inventive concept; however, it should be understood that more than two metal layers are typically present and indeed many other metal layers may be present.

A passivation layer 4, preferably an oxide, a nitride or a polyimide, is deposited on top of the top metal layer 1 in order to insulate the integrated circuit from environmental hazards. The thickness of the passivation layer 4 is preferably within a range of between 6000 Angstroms and 1 micrometer.

The structure depicted on FIG. 1 is fabricated according to common manufacturing techniques known to those skilled in the art.

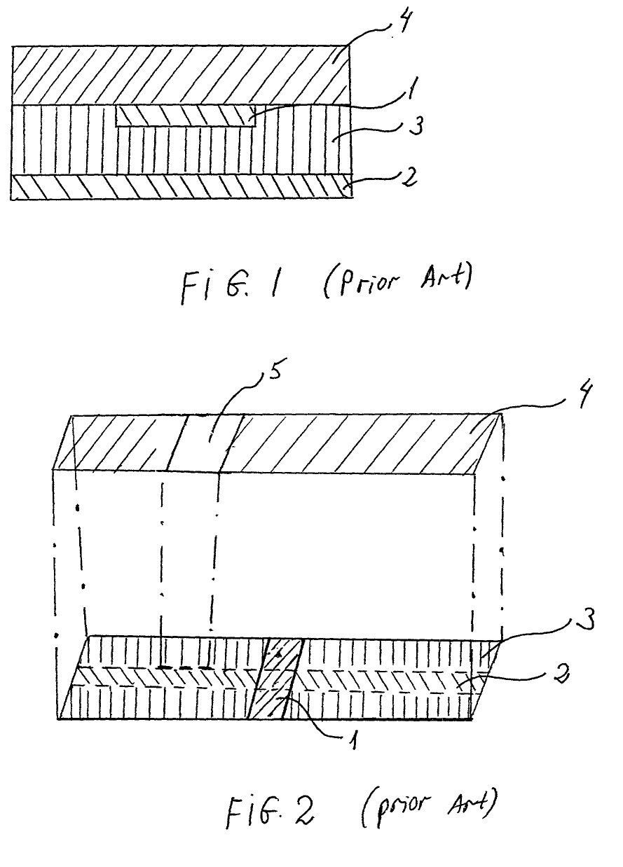

The two metal layers 1 and 2 are not typically disposed parallel to each other. Instead, they preferably run at an angle, more preferably, at a right angle. The exploded view shown on FIG. 2, reveals the relative locations of the metal layers 1 and 2. The passivation layer 4 is present in FIG. 2. Obviously, the metal layers 1 and 2 lie in different planes, the metal layer 1 being disposed on top of, and the metal layer 2 underneath, the insulating layer 3.

In accordance with the present invention, a passivation opening 5 is etched in the passivation layer 4. The passivation opening 5 is fabricated according to usual methods known to those skilled in the art. The passivation opening 5 is preferably located over the level of the metal layer 2, but in an area which is not over the top metal layer 1.

A reverse engineer must remove the passivation layer 4 first, typically, by etching the passivation layer 4 away, in order to be able to see the highest level metal layer 1, followed by further etching to remove the insulating layer 3 in order to see the next metal layer 2.

When, as shown on FIG. 3, following such practice, the reverse engineer etches the passivation layer 4 having the passivation opening 5 therein, in the region of the passivation opening the etchant will penetrate to and etch in the region 6 below the top metal layer 1, and possibly even as far as region 7, where the lower metal layer 2 lies, particularly when the size of the passivation opening 5 is sufficient.

The size of the passivation opening is not so large as to negatively impact the normal operation of the integrated circuit (i.e., causing corrosion) yet large enough to cause the destruction of the metal layer 2 beneath when an attempt to reverse-engineer is undertaken. A typical passivation opening is rectangular with a size of a side between about 1 micrometer and about 3 micrometers.

Even if the first etching step does not reach as far as region 7, then the next etching step, when the reverse engineer etches away the insulating layer 3 between the metal layers 1 and 2, will likely to etch the metal layer 2 away.

As a result, the reverse engineer inevitably will have destroyed the metal layer 2 and the information the metal layer 2 contained. Therefore, the reverse engineering of the whole integrated circuit will have failed and the reverse engineer would not be able to proceed further.

The alternative embodiments of this invention utilize the same concept and comprise making the passivation opening 5 over metal layers below the lower metal layer 2. Another embodiment comprises making an opening adjacent to contact openings as an offset in the normal opening.

Yet another embodiment using the same basic concept is to disable reading of memory such as, for example, electrically erasable programmable read-only memory (EEPROM). In this case the polycrystalline silicon (“poly”) level where the charge is stored is etched, thus discharging the memory bit.

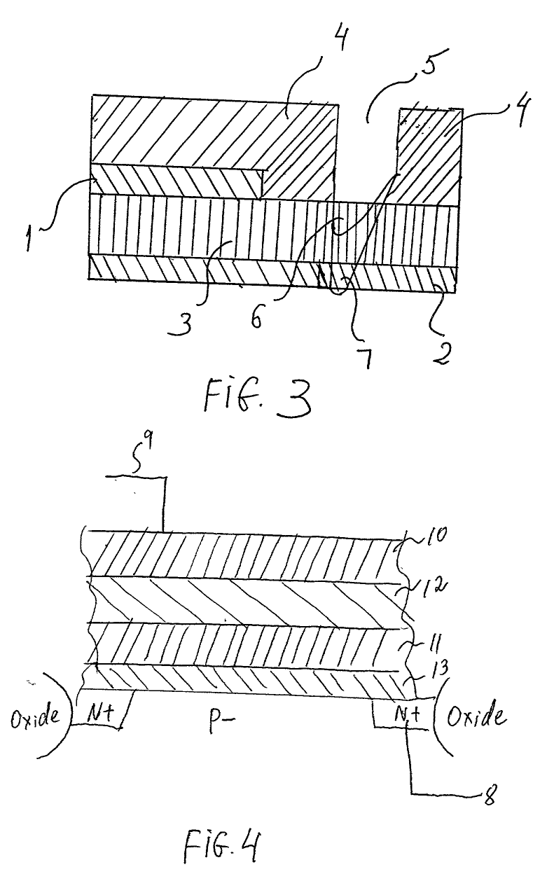

According to this embodiment, shown on FIG. 4, the structure comprises two metal layers 8 and 9, of which only one may be used to route signals, and two poly layers 10 and 11, each having a thickness of preferably about 1 micrometer and each separated by an appropriate insulator 12, preferably, an oxide or a nitride, having a thickness of preferably about 300 Angstroms. The structure also comprises a gate oxide layer 13, preferably having a thickness of about 100 Angstrom, n oxide area and N+ and P− areas as shown on FIG. 4. The first, or lower metal layer 8 can be the bit line, and the second metal layer 9—the word line. The word and bit lines typically overlap at the memory cell.

An opening in the passivation, placed about 1 micrometer from the memory cell, and not necessarily over the bit or the word lines, will enable the etchant to go rapidly down into the device and etch the poly layers. In particular, when the lowest poly layer 11 is etched, the charge on this so-called floating gate (which charge is the stored memory bit) is removed. As a result, the reverse engineer is prevented from reading the memory contents. In this embodiment, the passivation openings are automatically placed slightly offset from each memory cell.

Having described the invention in connection with several embodiments thereof, modification will now suggest itself to those skilled in the art. As such, the invention is not to be limited to the described embodiments except as required by the appended claims.

We claim:

1. A semiconducting device adapted to prevent and/or to thwart reverse engineering, comprising:
(a) an insulating layer disposed on a semiconductor substrate;
(b) a plurality of metal layers, said metal layers of said plurality being separated by said insulating layer, said plurality of said metal layers comprising a top metal layer and a number of lower metal layers disposed below said top metal layer;
(c) a passivation layer, said passivation layer being disposed above metal layer of said plurality of said metal layers; and
(d) a passivation opening defined within said passivation layer,
wherein said passivation opening has a location above all said metal layers, said location lying in a first vertical plane, and said top metal layer lying in a second vertical plane, said first vertical plane being spatially separated from said second vertical plane.

2. The device as claimed in claim 1, wherein said semiconducting device comprises integrated circuits.

3. The device as claimed in claim 1, wherein said insulating layer further comprises silicon oxide.

4. The device as claimed in claim 1, wherein said passivation layer further comprises either an oxide, a nitride, or a polyimide, or combinations thereof.

5. The device as claimed in claim 1, wherein said semiconducting devices further comprise electrically erasable programmable read-only memory.

6. The device as claimed in claim 1, wherein said insulating layer has a thickness within a range of between about 3,000 Angstroms and about 5,000 Angstroms.

7. The device of claim 1, wherein said metal layers have a thickness of about 200 Angstroms each.

8. The device as claimed in claim 1, wherein said passivation layer has a thickness within a range of between about 6000 Angstroms and about 1 micrometer.

9. The device as claimed in claim 1, wherein said location of said passivation opening is above one or more said lower metal layers.

10. The device as claimed in claim 2, wherein said integrated circuits further comprise complementary metal oxide-semiconductor, bi-polar silicon, or group III-group V integrated circuits.

11. A method for preventing and/or thwarting reverse engineering, comprising steps of:
(a) providing an insulating layer disposed on a semiconductor substrate;
(b) providing a plurality of metal layers whereby said metal layers of said plurality are separated by said insulating layer, said plurality of said metal layers comprising a top metal layer and a number of lower metal layers disposed below said top metal layer;
(c) providing a passivation layer whereby said passivation layer is disposed above metal layer of said plurality of said metal layers; and
(d) forming a passivation opening defined by said passivation layer,
said passivation opening being provided at a location above all said metal layers, said location being spatially separated from said top metal layer.

12. The method as claimed in claim 11, whereby when a process of reverse engineering is conducted, said process comprising etching using said passivation opening, portions of said semiconducting device are destroyed, wherein said portions of said semiconducting device being destroyed comprise said lower metal layers, and wherein said top metal layer may remain intact.

13. The method as claimed in claim 11, wherein said semiconducting device comprises an integrated circuit.

14. The method as claimed in claim 11, wherein said insulating layer further comprises silicon oxide.

15. The method as claimed in claim 11, wherein said passivation layer further comprises an oxide and/or a nitride.

16. The method as claimed in claim 11, wherein said semiconducting devices further comprise electrically erasable programmable read-only memory.

17. The method as claimed in claim 11, wherein said insulating layer has a thickness within a range of between about 3,000 Angstroms and about 5,000 Angstroms.

18. The method of claim 11, wherein said metal layers have a thickness of about 200 Angstroms each.

19. The method as claimed in claim 11, wherein said passivation layer has a thickness within a range of between about 6000 Angstroms and about 1 micrometer.

20. The method as claimed in claim 13, wherein said integrated circuits further comprise complementary metal oxide-semiconductor, bi-polar silicon, or group III-group V integrated circuits.

21. The method as claimed in claim 16, wherein said portions of said semiconducting device being destroyed comprise said electrically erasable programmable read-only memory, and wherein said top metal layer may remain intact.

22. The method as claimed in claim 11, wherein said location of said passivation opening is above one or more said lower metal layers.
